(19) United States
(12) Patent Application Publication
(10) Pub. No.: US 2009/0001594 A1
(43) Pub. Date: Jan. 1, 2009

(54) AIRGAP INTERCONNECT SYSTEM

(76) Inventors: Hui Jae Yoo, Hillsboro, OR (US); Makarem A. Hussein, Beaverton, OR (US); Jeffery D. Bielefeld, Forest Grove, OR (US); Vijayakumar S. Ramachandrarao, Portland, OR (US)

Correspondence Address: BUCKLEY, MASCHOFF & TALWALKAR LLC, 50 LOCUST AVENUE, NEW CANAAN, CT, 06840, US

(21) Appl. No.: 11/771,091

(22) Filed: Jun. 29, 2007

(51) Int. Cl. H01L 23/52; H01L 21/4763

(52) U.S. Cl. 257/773; 438/624; 257/E21.495; 257/E23.141

(57) ABSTRACT

A method may comprise assembling a first dielectric ensemble that comprises a first dielectric layer exhibiting a first porosity, a second dielectric layer exhibiting a second porosity and a third dielectric layer exhibiting a third porosity, and fabricating a first metal line in the dielectric ensemble. A chemical may be applied on the third layer to pass through and dissolve a portion of the second layer. The third layer acts to prevent a via that is partially landed on the dielectric from exposing the air gap underneath.

### BACKGROUND

Integrated circuits may comprise layers of metal lines and dielectric layers dispose there between. Air gaps may be used as dielectrics between metal lines in order to reduce signal delay and hence improve performance.

Air gaps as dielectrics may pose problems when used in conjunction with unlanded vias. An unlanded via is partially coupled to the dielectric between metal lines instead of to a metal portion of the metal line. During fabrication, the cavity in which an unlanded via is to be formed may accidentally penetrate the dielectric portion and expose an air gap on a lower dielectric layer. The air gap may then be filled with metal during the via metallization step, causing a short in a circuit.

### BRIEF DESCRIPTION OF THE DRAWINGS

FIG. 1 is a block diagram of a dielectric ensemble according to some embodiments.

FIG. 2 is a block diagram illustrating metal lines within a dielectric ensemble according to some embodiments.

FIG. 3 is a block diagram illustrating a creation of an air gap according to some embodiments.

FIG. 4 is a block diagram of an apparatus showing multi-level metallization according to some embodiments.

FIG. 5 is a block diagram of a process according to some embodiments.

### DETAILED DESCRIPTION

The several embodiments described herein are solely for the purpose of illustration. Embodiments may include any currently or hereafter-known versions of the elements described herein. Therefore, persons in the art will recognize from this description that other embodiments may be practiced with various modifications and alterations.

Referring now to FIG. 1, an embodiment of a dielectric ensemble 100 is shown. In some embodiments, the dielectric ensemble 100 may comprise a plurality of layers associated with an integrated circuit or a substrate. Each layer may be comprised of a different material and, each different material may be based on a carbon-doped oxide and or a spin-on dielectric material that exhibits a dielectric constant between 2.0-7.0. At least one dielectric layers is sacrificial and will be completely or partially removed during subsequent processing. Each layer may comprise similar dielectric properties that may allow the plurality of layers to be coupled to each other during manufacture. The dielectric ensemble 100 may be created during a single pass through a dielectric deposition tool. In some embodiments, the three layers may be deposited using a plasma enhanced chemical vapor deposition (PECVD) process. In some embodiments, the three layers may be deposited separately. In other embodiments, the ensemble 100 may be deposited using a plurality of PECVD and spin-on deposition steps.

The dielectric ensemble 100 may comprise any number of layers. In the illustrated embodiment, the dielectric ensemble 100 comprises a first dielectric layer 101, a second dielectric layer 102, and a third dielectric layer 103. In some embodiments, the first dielectric layer 101 may exhibit a first porosity and, in some embodiments, the first porosity may be zero (e.g. non-porous). In some embodiments, the first porosity may be between zero and ten percent. The first layer 101 may comprise an inter layer dielectric such as, but not limited to carbon-doped oxide. The second dielectric layer 102 may exhibit a second porosity and, in some embodiments, the second porosity may be approximately 15 to 25 percent (e.g. 15 to 25% porous). In this example, the second layer is considered sacrificial. The second layer 102 may comprise porous carbon-doped oxide in some embodiments. The third dielectric layer 103 may exhibit a third porosity. The third dielectric layer 103 may be referred to as a screen layer and in some embodiments the third porosity may be approximately 5 to 20 percent. An adhesive layer (not shown) may be coupled to the third layer to aid in integrating the dielectric ensemble 100.

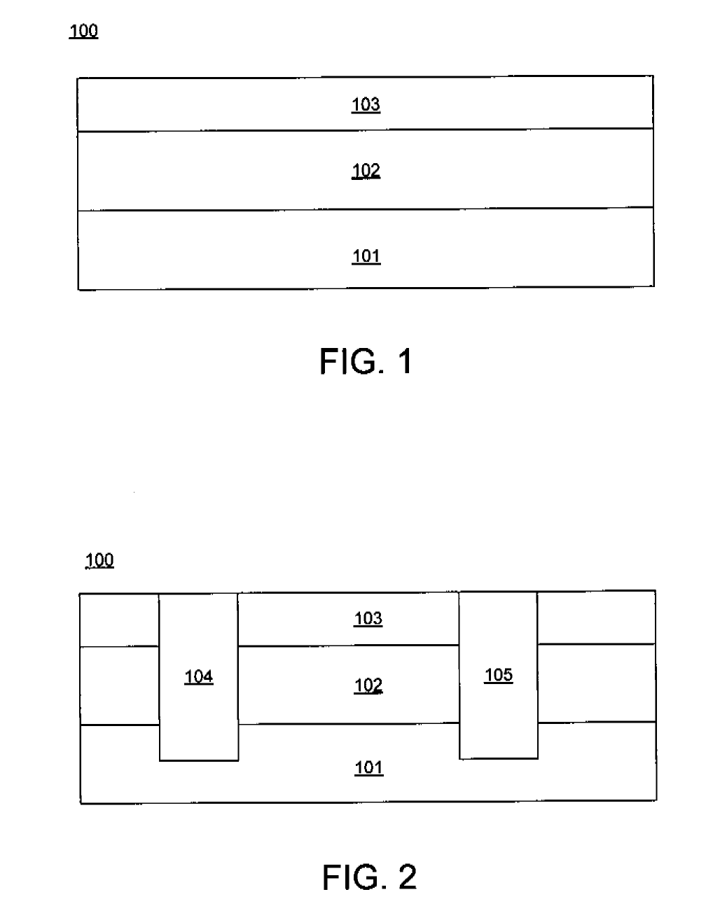

Now referring to FIG. 2, an embodiment of the dielectric ensemble 100 is illustrated. In FIG. 2, dielectric ensemble 100 may be patterned and metallized by forming one or more metal lines 104/105 using standard techniques, as known in the art. Each metal line is comprised of a metal stack. In some embodiments, each metal line 104/105 may be comprised of copper and copper diffusion barrier metal.

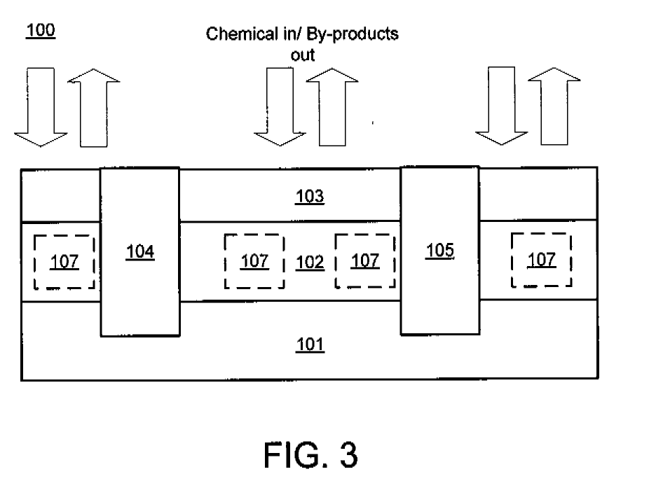

We now proceed to create the air gap 107 shown in FIG.3. FIG. 3 illustrates an embodiment of the dielectric ensemble 100 when subjected to a chemical with the purpose of dissolving all or part of the dielectric layer 102. The dielectric ensemble 100 may be as described with respect to FIG. 1 and, FIG. 2. However, as illustrated in FIG. 3, a chemical may be applied on the third layer 103, and because this layer is partially porous, the chemical may pass through and reach the second layer 102. In some embodiments the chemical may be applied by immersing the substrate shown in FIG.3 and/or by spraying the chemical. The chemical is formulated to attack (i.e. react with) the second layer 102 but not substantially attack the first layer 101, the third layer 103, the first metal line 104, or the metal line 105.

In some embodiments, the reaction may dissolve or strip all or part of the sacrificial second layer 102, resulting in one or more air gaps 107. The strip reaction byproducts may be extracted through the porous layer 103 leaving behind an air gap 107. In some embodiments, the one or more air gaps 107 may occupy 40 percent of the volume between the metal line 104 and 105. In some embodiments, the strip reaction byproducts may comprise a result of a reaction between the chemical and the second layer 102.

The utilization of the third layer 103 combined with design rules restricting the maximum space between two adjacent metal lines, preserves planarity of the substrate. In such case, no dielectric polish step is needed for the subsequent layer. A subsequent layer or ensemble may be applied directly on top of metal diffusion barrier layer.

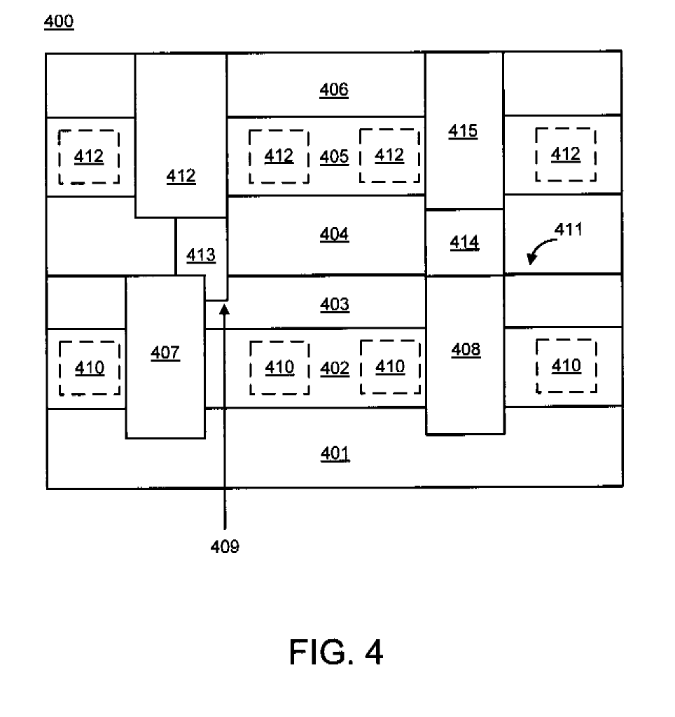

FIG. 4 illustrates an embodiment of a substrate 400 featuring multi-level metallization. The substrate 400 may comprise a plurality of dielectric ensembles and, as illustrated, the substrate 400 comprises a first dielectric ensemble (e.g. dielectric layers 401/402/403) and a second dielectric ensemble (e.g. dielectric layers 404/405/406). Dielectric layers 401 and 404 may be similar to dielectric layer 101 of FIG. 1 and FIG. 2. Moreover, dielectric layers 402 and 404 may be similar to dielectric layer 102 and dielectric layers 403 and 406 may be similar to dielectric layer 103.

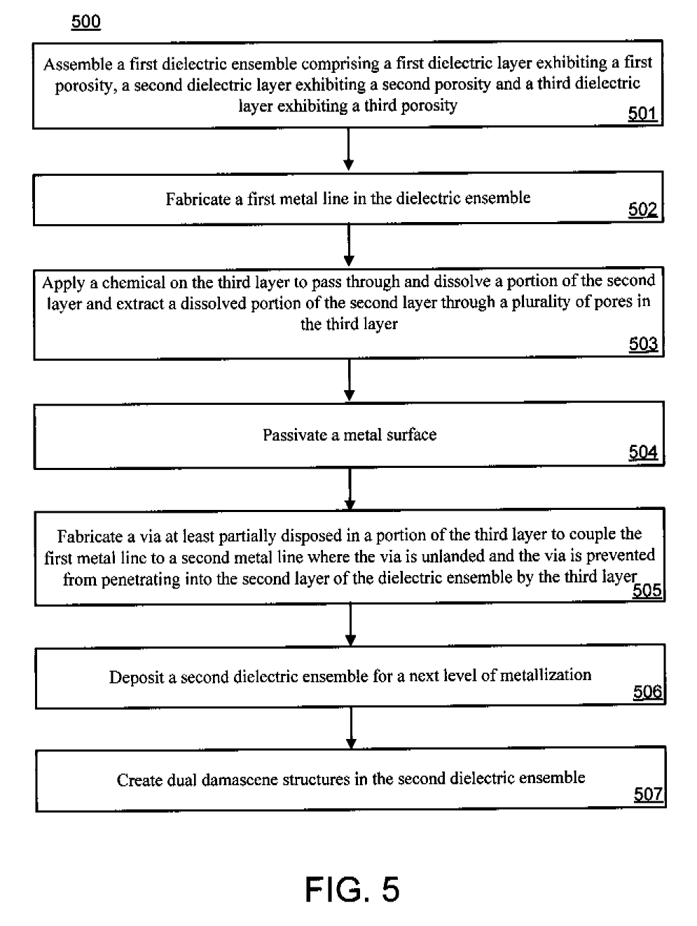

The first dielectric ensemble may be coupled to the second dielectric ensemble using a metal diffusion barrier layer 411. After each dielectric ensemble has been subjected to a process such as process 500 of FIG.5, a reaction with the second layer 402 and the fifth layer 405 may form a first air gap 410 between the first layer 401 and the third layer 403 and form a second air gap 412 between the fourth layer 404 and the sixth layer 406.

The substrate 400 may comprise a first via 413 and a second via 414. The first via 413 may couple a first metal line 407 to a second metal line 412. The second via 414 may couple a third metal line 408 to a fourth metal line 415. In some embodiments, the second via 414 may be fully landed. As illustrated at 409 a portion of the first via 413 lands on the dielectric 403 and thus the first via 413 is an unhanded via. Since the third dielectric layer 403 may be only 10 to 15 percent porous, the third dielectric layer 403 may maintain substantial rigidity such that the unlanded via 413 may not fully penetrate the third dielectric layer 403 thereby preventing the filling of the air gap during the subsequent metallization steps which may cause electrical shorts in the circuit of substrate 400.

Each via 413/414 may lie in at least a portion of the fourth layer 104. In some embodiments, the first via 413 and/or the second via may lie in a portion of the third layer 403.

FIG. 5 illustrates a process to fabricate the air gaps 107 in dual damascene metallization process, as described with respect to FIG. 3. At 501, a first dielectric ensemble comprising a first dielectric layer exhibiting a first porosity, a second dielectric layer exhibiting a second porosity and a third dielectric layer exhibiting a third porosity is assembled. Once the dielectric ensemble is deposited, a metal line may be fabricated at 502 using a damascene technique as known in the art. The damascene technique requires processes such as lithography, trench etch and cleans, metallization, and chemical-mechanical polishing of the deposited metal. In some embodiment, the metal line may be anchored in the first dielectric layer 101 of the ensemble. The metal line may be comprised of copper

Next, at 503, a chemical is applied on the third layer to pass through (e.g. permeate) and dissolve a portion of the sacrificial second layer and the dissolved portion of the sacrificial layer is extracted through a plurality of pores in the third layer. The chemical is to attack the second layer but is not to substantially react with the first layer, the third layer, or the substrate metals. Therefore, in some embodiments, the chemical may pass through the third layer and not pass through the first layer. The dissolution of the second layer may leave or form one or more air gaps between the first layer and the third layer. According to some embodiments, the chemical comprises diluted hydrofluoric acid. Any suitable chemical may be used in conjunction with some embodiments.

At 504, a metal surface is passivated. This is a step known in the art where either a thin dielectric layer 411 or a selectively deposited metal cap may be utilized. Next, at 505, a via is fabricated at least partially disposed in a portion of the third layer to couple the first metal line to a second metal line where the via is unlanded and the via is prevented from penetrating into the second layer of the dielectric ensemble by the third layer.

At 506, a second dielectric ensemble may be deposited for a next level of metallization. The second dielectric ensemble may comprise a fourth dielectric layer exhibiting the first porosity, a fifth dielectric layer exhibiting the second porosity and a sixth dielectric layer exhibiting the third porosity. Next, at 507, dual damascene structures may be created in the second dielectric ensemble.

In some embodiments a via disposed in at least a portion of the third layer and the fourth layer may be fabricated and may couple the first metal line to a second metal line where the via is fully landed as illustrated by via 414. In some embodiments, a via disposed in at least a portion of the third layer and the fourth layer may be fabricated to couple the first metal line to a second metal line where the via is unlanded as illustrated by via 413. Via 413 may be prevented from penetrating into the second layer of the dielectric ensemble by the third layer 403. A chemical may be applied on the sixth layer to pass through and dissolve a portion of the fifth layer and a dissolved portion of the fifth layer may be extracted through a plurality of pores in the sixth layer.

Since dielectric assemblies may be stacked to attain multi-level metallization, the method of FIG. 5 may be repeated such that multiple dielectric ensembles are assembled.

Various modifications and changes may be made to the foregoing embodiments without departing from the broader spirit and scope set forth in the appended claims.

What is claimed is:

1. A method comprising:
assembling a first dielectric ensemble comprising a first dielectric layer exhibiting a first porosity, a second dielectric layer exhibiting a second porosity and a third dielectric layer exhibiting a third porosity;
fabricating a first metal line in the dielectric ensemble;
applying a chemical on the third layer to pass through and dissolve a portion of the second layer; and
fabricating a via at least partially disposed in a portion of the third layer to couple the first metal line to a second metal line where the via is unlanded and the via is prevented from penetrating into the second layer of the dielectric ensemble by the third layer.

2. The method of claim 1, further comprising:
extracting a dissolved portion of the second layer through a plurality of pores in the third layer.

3. The method of claim 1, further comprising:
assembling a second dielectric ensemble comprising a fourth dielectric layer exhibiting the first porosity, a fifth dielectric layer exhibiting the second porosity and a sixth dielectric layer exhibiting the third porosity;
applying a chemical on the sixth layer to pass through and dissolve a portion of the fifth layer; and
extracting a dissolved portion of the fifth layer through a plurality of pores in the sixth layer.

4. The method of claim 1, wherein the first dielectric layer exhibits a porosity of approximately zero percent, the second dielectric layer exhibits a porosity of approximately 25 percent, and the third dielectric layer exhibits a porosity of approximately 15 percent.

5. The method of claim 1, at least one layer of the dielectric ensemble is sacrificial.

6. The method of claim 1, wherein the chemical is to react with the second layer but is to not react with the first layer, the third layer, or substrate metals.

7. The method of claim 1, wherein the chemical is to pass through the third layer and not pass through the first layer.

8. The method of claim 1, wherein the chemical is to strip the second layer and form an air gap between the first layer and the third layer.

9. The method of claim 1, wherein the third layer is to remain planar after the chemical is applied.

10. An integrated circuit comprising:
a first integrated circuit substrate layer comprising:
a first metal line; and
a first dielectric ensemble to be exposed to a chemical, the first dielectric ensemble comprising a first dielectric layer exhibiting a first porosity, a second dielectric layer exhibiting a second porosity and a third dielectric layer exhibiting a third porosity; and
a second integrated circuit board layer comprising:
a second metal line coupled to the first metal line by a via; and
a second dielectric ensemble to be exposed to the chemical, the second dielectric ensemble comprising a fourth dielectric layer exhibiting the first porosity, a fifth dielectric layer exhibiting the second porosity and a third dielectric layer exhibiting the third porosity,
wherein the via is disposed in at least a portion of the third layer and the fourth layer and is to couple the first metal line to the second metal line where the via is unlanded and the via is prevented from further penetration of the first dielectric ensemble by the third layer.

11. The integrated circuit of claim 10, wherein the first and fourth dielectric layers exhibit a porosity of approximately zero to 10 percent, the second dielectric layer exhibits a porosity of approximately 15 to 25 percent, and the third layer dielectric exhibits a porosity of approximately 5 to 20 percent.

12. The integrated circuit of claim 10, wherein the chemical is to chemically react with the second layer and fifth layer but is to not react with the first layer, the third layer, the fourth layer, the sixth layer, the first metal line, or the second metal line.

13. The integrated circuit of claim 10, wherein the chemical passes through the third layer and not through the first layer, and wherein the liquid pass through the sixth layer and not through the fourth layer.

14. The integrated circuit of claim 13, wherein the chemical reacts with the second layer and the fifth layer, and forms an air gap between the first layer and the third layer and forms an air gap between the fourth layer and the sixth layer respectively.

15. The integrated circuit of claim 14, wherein the chemical reaction creates a byproduct, the byproduct comprising a result of the reaction between the chemical and the second layer and is extruded through the third layer.

16. The integrated circuit of claim 15, wherein the third layer and the sixth layer are to remain planar after the chemical reaction.
